(19) United States
(12) Patent Application Publication
(10) Pub. No.: US 2013/0213802 A1
(43) Pub. Date: Aug. 22, 2013

(54) Sintered Compact Sputtering Target

(71) Applicants: Atsushi Sato, Ibaraki (JP); Yuichiro Nakamura, Ibaraki (JP)

(72) Inventors: Atsushi Sato, Ibaraki (JP); Yuichiro Nakamura, Ibaraki (JP)

(73) Assignee: JX NIPPON MINING & METALS CORPORATION, Tokyo (JP)

(21) Appl. No.: 13/878,438

(22) PCT Filed: Dec. 2, 2011
(86) PCT No.: PCT/JP2011/077897

§ 371 Date: Apr. 9, 2013

(30) Foreign Application Priority Data
Dec. 22, 2010 (JP) 2010-286308

(51) Int. Cl. C23C 14/34

(52) U.S. Cl. CPC C23C 14/3407
USPC 204/298.13; 264/681

(57) ABSTRACT

A sintered compact sputtering target is provided and contains Co and Cr as metal components and includes oxides dispersed in the structure formed of the metal components. The structure of the sputtering target has a region (A) containing Co oxides dispersed in Co and a region (D) containing Cr oxides in a periphery of the region (A). In addition a method of producing the above referenced sintered compact sputtering target is provided and includes the steps of mixing a powder prepared by pulverizing a sintered compact containing Co oxide dispersed in Co, a Co powder, and a Cr power and pressure-sintering the resulting powder mixture to provide a sputtering target.

### BACKGROUND

The present invention relates to a magnetic material sputtering target to be used for producing a perpendicular magnetic recording film, in particular, a sintered compact sputtering target composed of a magnetic material of a Co—Cr-oxide system or a Co—Cr—Pt-oxide system to be used for a magnetic layer, and relates to a method of producing the target.

In the field of magnetic recording/reproducing divices represented by hard disk devices, a perpendicular magnetic recording system in which an axis of easy magnetization is oriented in the direction perpendicular to a recording surface is practically used. In particular, in a hard disk medium employing a perpendicular magnetic recording system, a magnetic film having a granular structure, in which perpendicularly oriented magnetic crystalline particles are surrounded by a nonmagnetic material to decrease the magnetic interaction between the magnetic particles, has been developed for an increase in recording density and a decrease in noise.

In the granular structure-type magnetic film of which magnetic particle material is a ferromagnetic alloy primarily composed of Co, such as a Co—Cr—Pt alloy, the nonmagnetic material is usually a metal oxide such as SiO₂ or TiO₂.

In a known method of producing the granular structure-type magnetic film, a complex sputtering target composed of a Co-base alloy and a nonmagnetic material is sputtered with a DC magnetron sputtering device. In the methods described in the literatures mentioned below, a nonmagnetic material is added to a ferromagnetic material primarily composed of a Co—Cr—Pt alloy.

In general, a complex sputtering target composed of a Co-base alloy and a nonmagnetic material is produced by a powder metallurgical process, because of necessity of uniform dispersion of nonmagnetic material particles in an alloy base. For example, a method of preparing a sputtering target for magnetic recording media is proposed (Patent Literature 1). In this method, an alloy powder having an alloy phase produced by rapid solidification and a powder constituting a ceramic phase are mechanically alloyed to uniformly disperse the powder constituting a ceramic phase in the alloy powder, and then the dispersion is molded with a hot press.

Incidentally, in sputtering of a complex sputtering target, a metal oxide may be decomposed into a metal and oxygen, and the metal generated by the decomposition may penetrate in the magnetic crystalline particles and cause to decrease the magnetic characteristics. In order to solve the problem, Patent Literature 2 proposes sputtering with a sputtering target containing an appropriate amount of Co oxide.

The method intends to cause an effect of segregating a stable metal oxide between magnetic particles through recombination of the metal element of a metal oxide decomposed during sputtering with oxygen generated by decomposition of Co oxide.

Though Patent Literature 2 describes that the target includes a Co alloy; Ti oxide and Si oxide for forming a first oxide; and Co oxide for forming a second oxide and that the total amount of the first oxide in the target is about 12 mol % or less as the molar fraction, the invention of Patent Literature 2 relates to a magnetic recording medium and does not define any composition range effective as a target.

Patent Literature 3 describes a sputtering target containing (Co and Pt) or (Co, Cr, and Pt), SiO₂ and/or TiO₂, and Co₃O₄ and/or CoO. In this case, the content of Co₃O₄ and/or CoO is 0.1 to 10 mol %. There is a description that sintering of a raw material powder at a temperature of 1000° C. or less prevents oxides such as SiO₂, TiO₂, CO₃O₄, and CoO from being reduced and provides a relative density of 94% or more.

It is disclosed that sintering at 1000° C. or less can prevent CoO from being reduced, but, how much Co₃O₄ and/or CoO remains in the sputtering target is not specifically investigated.

Patent Literature 4 describes a magnetic recording medium containing a Co alloy; at least one first oxide selected from the group consisting of oxides of Si, Ti, Ta, Cr, W, and Nb; and Co oxide constituting a second oxide, but does not define any composition range effective as a target.

Patent Literature 1: Japanese Patent Application Laid-Open No. H10-088333

Patent Literature 2: Japanese Patent Application Laid-Open No. 2009-238357

Patent Literature 3: International Publication No. WO 2010074171

Patent Literature 4: Japanese Patent Application Laid-Open No. 2009-170052

### SUMMARY OF THE INVENTION

### Technical Problem

In a Co—Cr-oxide system target or a Co—Cr—Pt-oxide system target, the oxide is usually SiO₂, Cr₂O₃, or TiO₂.

However, the metal oxide in a target may be decomposed into a metal and oxygen during sputtering and the metal generated by the decomposition may penetrate in the magnetic crystalline particles to decrease the magnetic characteristics.

In order to solve the problem, a method of providing a predetermined amount of Co oxide in a target, as described above, is proposed. This method intends to cause a phenomenon of segregating a stable metal oxide between magnetic particles through recombination of the metal element of a metal oxide decomposed during sputtering with oxygen generated by decomposition of Co oxide. The method has a considerably advantageous effect compared with other conventional methods.

The production of a Co—Cr-oxide system target or a Co—Cr—Pt-oxide system target by sintering a mixture containing a Co oxide powder in addition to powders for sintering, however, causes a problem that the Co oxide is reduced by Cr to form Cr oxide depending on the sintering temperature. It means that the Co oxide in a target disappears, which cannot achieve the original aim of allowing the Co oxide to remain.

The residual amount of Co oxide can be increased by significantly decreasing the sintering temperature, however, which makes it hard to sufficiently increase the density of the target because the sintering reaction is prevented from proceeding. A low density target has problems such as occurrence of many particles during sputtering.

It is an object of the present invention to provide Co—Cr-oxide system and Co—Cr—Pt-oxide system magnetic material targets that have a required amount of Co oxide remaining and have a sufficient sintering density to decrease the occurrence of particles during sputtering.

### Solution to Problem

In order to solve the above-mentioned problems, the present inventors have performed diligent studies and, as a result, have found that a sintered compact sputtering target that has a required amount of Co oxide remaining in the target and has a sufficiently high sintering density can be prepared by regulating the mixing of powders.

Based on such findings, the present invention provides:

1) a sintered compact sputtering target comprising a metal base containing Cr and Co as the metal components and an oxide dispersed in the base, wherein the sputtering target has a structure in which a region (A) containing Co oxide dispersed in Co and a region (D) containing Cr oxide and being present in the periphery of the region (A) are included in the metal base; and

2) the sintered compact sputtering target according to 1) above, wherein the target includes Cr in an amount of 0.5 mol % or more and 45 mol % or less as the metal component.

The present invention further provides:

3) a sintered compact sputtering target comprising a metal base containing Co, Cr, and Pt as the metal components and an oxide dispersed in the base, wherein the sputtering target has a structure in which a region (A) containing Co oxide dispersed in Co or a region (B) containing Co oxide dispersed in Pt or a region (C) containing Co oxide dispersed in Co—Pt and a region (D) containing Cr oxide and being present in the periphery of the region (A), (B), or (C) are included in the metal base; and

4) the sintered compact sputtering target according to 3) above, wherein the target comprises Cr in an amount of 0.5 mol % or more and 30 mol % or less and Pt in an amount of 0.5 mol % or more and 30 mol % or less as the metal components.

The present invention further provides:

5) the sintered compact sputtering target according to any one of 1) to 4) above, wherein the Co oxide is at least one selected from CoO, Co₂O₃, and Co₃O₄; and

6) the sintered compact sputtering target according to any one of 1) to 5) above, wherein the Co oxide has a volume fraction of 1 vol % or more and 20 vol % or less with respect to the sputtering target.

The present invention further provides:

7) the sintered compact sputtering target according to any one of 1) to 6) above, further comprising at least one oxide of element selected from Co, Cr, B, Mg, Al, Si, Ti, V, Mn, Y, Zr, Nb, Ta, and Ce as an oxide dispersed in the metal base in a region other than the region (A), (B), or (C) and the region (D).

The present invention further provides:

8) the sintered compact sputtering target according to any one of 1) to 7) above, further comprising at least one element selected from B, Ti, V, Nb, Mo, Ru, Ta, W, Ir, and Au in an amount of 15 mol % or less as a metal component; and

9) the sintered compact sputtering target according to any one of 1) to 8) above, having a relative density of 90% or more.

The present invention further provides:

10) a method of producing a sintered compact sputtering target comprising a metal base containing Co and Cr as the metal components and an oxide dispersed in the base, the method comprising mixing a powder prepared by pulverizing a sintered compact containing Co oxide dispersed in Co, a Co powder, and a Cr power; and pressure-sintering the resulting powder mixture to provide a sputtering target having a structure in which a region (A) containing Co oxide dispersed in Co and a region (D) containing Cr oxide and being present in the periphery of the region (A) are included in the metal base.

11) the method of producing a sintered compact sputtering target according to 10) above, wherein the target comprises Cr in an amount of 0.5 mol % or more and 45 mol % or less as the metal component.

The present invention further provides:

12) a method of producing a sintered compact sputtering target comprising a metal base containing Co, Cr, and Pt as the metal components and an oxide dispersed in the base, the method comprising mixing a powder prepared by pulverizing a sintered compact containing Co oxide dispersed in Co, Pt, or Co—Pt, a Co powder, a Pt powder, and a Cr power; and pressure-sintering the resulting powder mixture to provide a sputtering target having a structure in which a region (A) containing Co oxide dispersed in Co or a region (B) containing Co oxide dispersed in Pt or a region (C) containing Co oxide dispersed in Co—Pt and a region (D) containing Cr oxide and being present in the periphery of the region (A), (B), or (C) are included in the metal base.

13) the method of producing a sintered compact sputtering target according to 12) above, wherein the target comprises Cr in an amount of 0.5 mol % or more and 30 mol % or less and Pt in an amount of 0.5 mol % or more and 30 mol % or less as the metal components.

The present invention further provides:

14) the method of producing a sintered compact sputtering target according to any one of 10) to 13) above, wherein the Co oxide is at least one selected from CoO, Co₂O₃, and Co₃O₄; and

15) the method of producing a sintered compact sputtering target according to any one of 10) to 14) above, wherein the Co oxide has a volume fraction of 1 vol % or more and 20 vol % or less with respect to the sputtering target.

The present invention further provides:

16) the method of producing a sintered compact sputtering target according to any one of 10) to 15) above, wherein the powder mixture for sintering further comprises at least one oxide of element selected from Co, Cr, B, Mg, Al, Si, Ti, V, Mn, Y, Zr, Nb, Ta, and Ce as an oxide to be dispersed in the metal base in a region other than the region (A), (B), or (C) and the region (D).

The present invention further provides:

17) the method of producing a sintered compact sputtering target according to any one of 10) to 16) above, wherein the metal powder for sintering further comprises at least one element selected from B, Ti, V, Nb, Mo, Ru, Ta, W, Ir, and Au in an amount of 15 mol % or less as a metal component; and

18) the method of producing a sintered compact sputtering target according to any one of 10) to 17) above, wherein the sintered compact target has a relative density of 90% or more.

The present invention can provide Co—Cr-oxide system and Co—Cr—Pt-oxide system sintered compact sputtering targets having a region (A), (B), or (C) containing dispersed Co oxide. The region (A) containing Co oxide dispersed in Co or the region (B) containing Co oxide dispersed in Pt, or the region (C) containing Co oxide dispersed in Co—Pt is dispersed in a base (matrix) of a Co—Cr alloy or a Co—Cr—Pt alloy, and region (D) containing Cr oxide is formed by a reaction of Co oxide with Cr diffused during sintering in the periphery of the region (A), (B), or (C).

In this case, the use of a powder prepared by pulverizing a sintered compact containing Co oxide dispersed in Co, a sintered compact containing Co oxide dispersed in Pt, or a sintered compact containing Co oxide dispersed in Co—Pt as a sintering raw material prevents Co oxide from coming into direct and full-scale contact with Cr even in a temperature range in which the sintering reaction sufficiently proceeds. That is, Co functions as a buffer to prevent the contact.

As a result, a region where Co oxide is dispersed is formed in the sintered compact sputtering target. Thus, the present invention has an excellent effect of providing Co—Cr-oxide system and Co—Cr—Pt-oxide system magnetic material targets that have a required amount of Co oxide remaining and decrease the occurrence of particles during sputtering to give a sufficient sintering density.

### BRIEF DESCRIPTION OF DRAWINGS

FIG. 1 is a microscopic photograph showing a polished structure of a powder prepared by pulverizing a sintered compact containing CoO dispersed in Co.

FIG. 2 is a photograph showing a typical structure produced by mixing a Cr powder, a Co powder, and a powder prepared by pulverizing a sintered compact containing CoO dispersed in Co and pressure-sintering the resulting powder mixture.

FIG. 3 is an explanatory drawing of FIG. 2 and illustrating the state of a sintered compact structure including a region (A) containing CoO dispersed in Co and a region (D) containing Cr oxide and being present in the periphery of the region (A).

### DETAILED DESCRIPTION OF THE INVENTION

The sintered compact sputtering target of the present invention includes a metal base containing Co and Cr as the metal components and an oxide dispersed in the base or includes a metal base containing Co, Cr, and Pt as the metal components and an oxide dispersed in the base. The sputtering target has a structure in which a region (A) containing Co oxide dispersed in Co or a region (B) containing Co oxide dispersed in Pt or a region (C) containing Co oxide dispersed in Co—Pt (alloy) and a region (D) containing Cr oxide and being present in the periphery of the region (A), (B), or (C) are included in the metal base.

The composition of the sputtering target of the present invention is limited to the above-mentioned composition range for obtaining a preferred composition as a magnetic layer material of a hard disk medium employing a perpendicular magnetic recording system. The structure of the sputtering target has a region (A) containing Co oxide dispersed in Co or a region (B) containing Co oxide dispersed in Pt or a region (C) containing Co oxide dispersed in Co—Pt (alloy) and a region (D) containing Cr oxide are included in a metal base (matrix), and thereby the magnetic layer produced using the sputtering target of the present invention has a granular structure satisfactory as a perpendicular magnetic recording medium.

The presence of the region (A) containing Co oxide dispersed in Co, the region (B) containing Co oxide dispersed in Pt, or the region (C) containing Co oxide dispersed in Co—Pt is an important structural requirement in the sintered compact sputtering target of the present invention. Also, the presence of the region (D) containing Cr oxide in the periphery of the region (A), (B), or (C) is the distinctive feature of the present invention.

Thus, Cr diffused during sintering reacts with Co oxide in the periphery of the region (A) containing Co oxide dispersed in Co, the region (B) containing Co oxide dispersed in Pt, or the region (C) containing Co oxide dispersed in Co—Pt to form the region (D) containing Cr oxide. The formation of Cr oxide by the diffusion of Cr can possibly be affected by the types of the raw material powders and sintering conditions, and therefore the Cr oxide is not necessarily dispersed uniformly in the region (D).

However, the use of a powder prepared by pulverizing a sintered compact containing Co oxide dispersed in Co, Pt, or Co—Pt (alloy) as a sintering raw material prevents the Co oxide from coming into direct and full-scale contact with Cr even in a temperature range in which the sintering reaction sufficiently proceeds, and the use eventually forms a structure having the region (D) in the periphery of the region (A), (B), or (C) so as to surround the periphery.

The region (A), (B), and (C) may disappear by the diffusion of Cr under some sintering conditions, but such excess sintering must be avoided, since it is an object of the present invention to allow a required amount of Co oxide to remain in the target.

The cross-sectional shapes of the regions (A), (B), and (C) and the double-layer with the region (D) formed in the periphery of the region (A), (B), or (C) may be circular, or spherical in three dimensions, elliptical, island-like, or irregular like amoeba, namely undefined shape as shown in FIG. 2, and the present invention encompasses all of these shapes.

The sputtering target of the present invention is produced by a powder sintering method. Thus, the above-mentioned regions may not be necessarily clearly separated from one another, but the structure having the above-mentioned shapes can be observed in the sputtering target of the present invention.

In the region (A) containing Co oxide dispersed in Co, the region (B) containing Co oxide dispersed in Pt, or the region (C) containing Co oxide dispersed in Co—Pt, an element other than Co or Pt and an oxide other than Co oxide may be recognized due to mutual diffusion during sintering and the influence of trace impurities contained in the raw material powders. In such a case, however, the main structural elements of the region (A) are Co and Co oxide, and as long as these main components are contained, a small amount of contamination is negligible. The present invention encompasses such cases.

The Co oxide can be at least one selected from CoO, Co₂O₃, and Co₃O₄. The Co oxide may have any form without causing any particular disadvantage. As described above, the presence of Co oxide is desirable in the light of forming a film of the magnetic material. The volume fraction of the Co oxide occupying the sputtering target is preferably 1 vol % or more and 20 vol % or less. A volume fraction of less than 1 vol % makes achievement of the effect difficult, whereas a volume fraction of higher than 20 vol % makes maintaining of Co oxide as a specific condition difficult and may deteriorate the characteristics as a magnetic recording film. Thus, the above-mentioned range is desirable.

The magnetic material sputtering target used for producing a perpendicular magnetic recording film can contain at least one oxide of element selected from B, Mg, Al, Si, Ti, V, Mn, Y, Zr, Nb, Ta, and Ce, as the oxide other than Co oxide and Cr oxide.

These oxides have standard free energies of formation higher than that of Co oxide and recombine with oxygen generated by decomposition of Co oxide during sputtering into oxides, which precipitate in grain boundaries. Thus, these oxides are preferable as materials of a magnetic layer.

Preferably, the content of oxides including Co oxide and Cr oxide is 40 vol % or less as the volume fraction occupying the sputtering target. A volume fraction of higher than 40 vol % tends to decrease the characteristics as a sputtering target for a perpendicular magnetic recording film, and thereby the foregoing range is preferred.

The sputtering target can contain at least one element selected from B, Ti, V, Nb, Mo, Ru, Ta, W, Ir, and Au as an additional element in a blending ratio of 15 mol % or less as a metal component in the sputtering target. These elements are effective as the magnetic materials used for producing a perpendicular magnetic recording film, as well as Co, Cr, and Pt, and are added to the sputtering target, as necessary, for further improving the characteristics of a magnetic recording film.

The sputtering target of the present invention can have a relative density of 90% or more to prevent occurrence of particles due to a lack of density. More preferably, the relative density is 95% or more, and the present invention can thus increase the relative density.

The relative density in the present invention is a value determined by dividing the measured density of a sputtering target by the calculated density (theoretical density). The calculated density is a density when it is assumed that the constituents of a target are mixed without diffusing to or reacting with each other and is calculated by the following formula.

Formula: calculated density=Σ[(molecular weight of a constituent)×(molar ratio of the constituent)]/Σ[(molecular weight of the constituent)×(molar ratio of the constituent)/(literature value density of the constituent)]

Here, Σ means taking the sum of all target constituents. The measured density of a sputtering target is a value measured by an Archimedes method.

The sputtering target of the present invention is produced by a powder sintering method. As a starting material, a powder prepared by pulverizing a sintered compact containing Co oxide dispersed in Co, Pt, or Co—Pt (alloy) produced in advance is used. This pulverized powder desirably has an average particle diameter of 30 to 200 μm. In addition, a powder of a metal (Co, Pt, Cr, or additional element) having an average particle diameter of 20 μm or less can be used for controlling the composition. Furthermore, not only a metal powder of a single element, but also an alloy powder can be used. In such a case also, the average particle diameter is desirably 20 μm or less. If the average particle diameter of a metal powder is 20 μm or more, the driving force for sintering is low, resulting in a problem that the density of the sintered compact hardly increases.

Meanwhile, if a particle diameter is too small, oxidation of a metal powder will cause problems such as a deviation of the component composition from the necessary range. Thus, the diameter is further desirably 0.5 μm or more.

These should be controlled by the component composition and sintering conditions such as temperature and pressure, and therefore, are within suitable ranges that are usually performed. Accordingly, it should be readily understood that sizes other than the above-mentioned sizes are also applicable.

Oxide powders other than Co oxide desirably have a maximum particle diameter of 5 μm or less because of necessity of being finely dispersed in a metal. Meanwhile, since too small a particle diameter readily causes aggregation, the diameter is further desirably 0.1 μm or more.

First, a powder prepared by pulverizing a sintered compact containing Co oxide dispersed in Co, Pt, or Co—Pt (alloy), a metal powder, and an oxide powder according to need are weighed to give a desired composition. Subsequently, the weighed powders are mixed by a known method such as a ball mill or a mixer. The thus-prepared powder mixture is molded and sintered by hot press. Instead of the hot press, spark plasma sintering or hot hydrostatic pressure sintering may be employed.

The retention temperature for the sintering is set in a range of 800 to 1200° C., but more preferably 850 to 1100° C. The sintered compact for a sputtering target of the present invention can be produced by the steps described above.

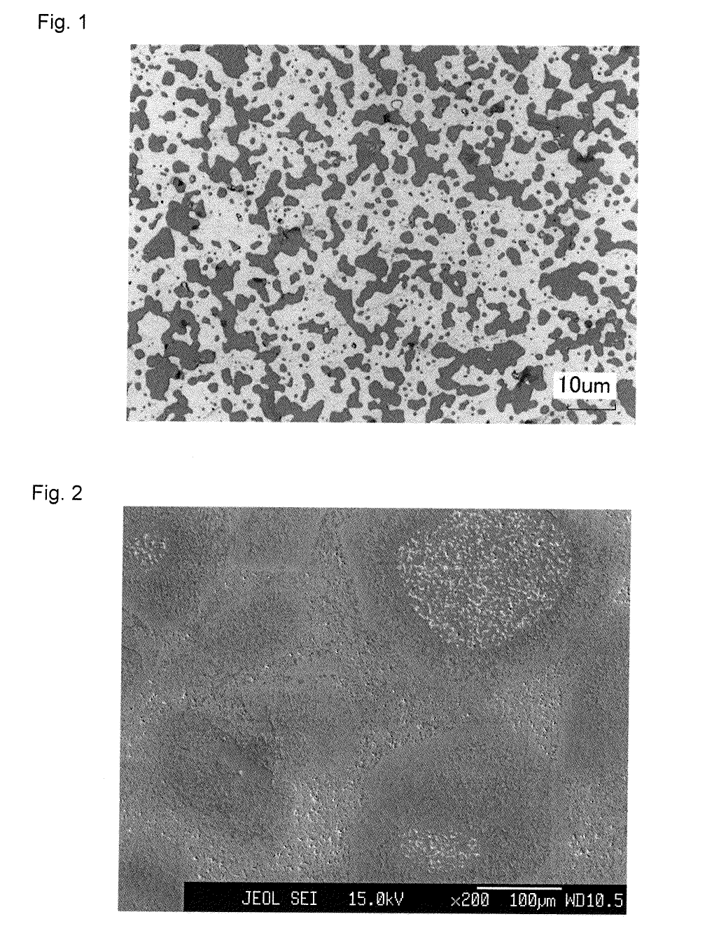

FIG. 1 is a microscopic photograph showing a polished structure of a powder prepared by pulverizing a sintered compact containing Co oxide (CoO) dispersed in Co. In FIG. 1, the white base (matrix) of particles shows Co, and the slightly black flake portion shows CoO. Thus, CoO is dispersed in a Co base. A powder prepared by pulverizing a sintered compact containing Co oxide dispersed in Pt and a powder prepared by pulverizing a sintered compact containing Co oxide dispersed in Co—Pt (alloy) also provide similar structures.

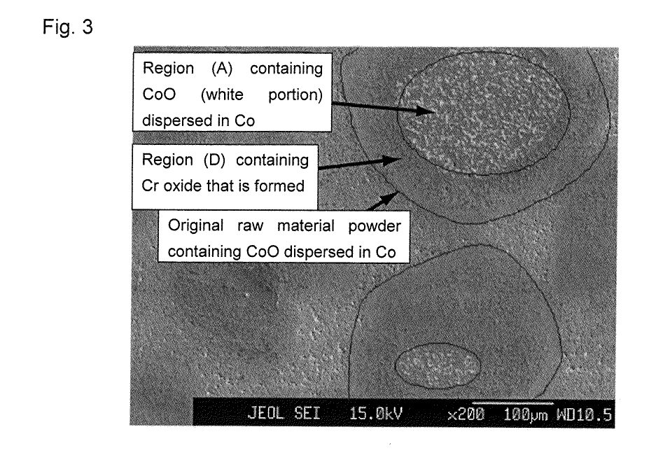

FIG. 2 is a photograph showing a typical structure produced by mixing the powder shown in FIG. 1, a Cr powder, and a Co powder and pressure-sintering the resulting powder mixture. FIG. 3 is an explanatory drawing of FIG. 2.

As shown in FIGS. 2 and 3, the sintered compact structure includes a region (A) containing CoO dispersed in Co, and a region (D) containing Cr oxide is observed in the periphery of the region (A).

This region (D) containing Cr oxide is newly formed through reduction of CoO in the original raw material powder, which contains the CoO as a dispersoid in Co, by Cr diffused from the periphery in the sintering process. The region (D) containing Cr oxide has a large thickness when the sintering temperature is high and the sintering time is long, and ultimately the region (A) containing CoO dispersed in Co disappears.

The disappearance of the region (A) containing Co oxide dispersed means, as described above, that the effect of segregating a stable metal oxide between magnetic particles through recombination of a metal element of a metal oxide decomposed during sputtering with oxygen generated by decomposition of Co oxide cannot be obtained. The disappearance of the region (A) is therefore not preferable.

The structure shown in FIGS. 2 and 3 includes the region (A) containing Co oxide dispersed in Co and is therefore a preferred form.

A case of a sintered compact sputtering target structure including a metal base and a region (A) containing CoO dispersed in Co in the metal base has been described in the above. Similar structures and functions are obtained in the case of a sintered compact sputtering target structure including a region (B) containing Co oxide dispersed in Pt or a region (C) containing Co oxide dispersed in Co—Pt.

### EXAMPLES

The present invention will now be described based on examples and comparative examples. The examples are merely illustrative, and the present invention shall in no way be limited thereby. In other words, the present invention shall only be limited by the scope of claims, and encompasses various modifications in addition to the examples included in this invention.

### Example 1

This is a case of using Co—CoO powder in production of Co—Cr—Cr₂O₃—CoO sputtering target.

A Co powder having an average particle diameter of 3 μm and a Cr powder having an average particle diameter of 5 μm as metal powders, and a Co—CoO powder having an average particle diameter of 150 μm prepared by pulverizing a sintered compact containing CoO dispersed in Co (composition: Co-25 mol % CoO) were prepared.

The powders were weighed at the following weight ratio to be 1836.1 g in total.

Weight ratio: 25.39 Co-12.06 Cr-62.55 (Co—CoO) (wt %)

This weight ratio is represented by the following molecular weight ratio.

Molecular weight ratio: 71 Co-14 Cr-15 CoO (mol %)

Subsequently, the weighed metal powders were placed in a 10-liter ball mill pot together with zirconia balls as a pulverizing medium, and the ball mill pot was sealed and rotated for 2 hours for mixing and pulverization. The powder mixture taken out from the ball mill was further mixed with the Co—CoO powder with a planetary screw mixer having a ball capacity of about 7 liters for 10 minutes. The powder mixture taken out from the planetary screw mixer was filled in a carbon mold and was hot-pressed.

The hot-press conditions were a vacuum atmosphere, a rate of temperature rise of 300° C./hour, a retention temperature of 1050° C., and a retention time of 2 hours, and a pressure of 30 MPa was applied to the mold from the start of the temperature rise till the completion of the retention.

The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 97.5%. A small piece cut from the sputtering target was subject to composition analysis with an ICP emission spectrophotometric analyzer. The composition of the sputtering target calculated based on the analytic result was as follows.

79.23 Co-9.56 Cr-3.01 Cr₂O₃-8.20 CoO (mol %)

The volume fraction of Co oxide calculated from the target composition was 12.3 vol %. A part of the sputtering target was cut out, and the cross section thereof was polished to observe the structure. A region (A) containing CoO dispersed in Co and a region (D) containing Cr oxide being present in the periphery of the region (A) were observed.

From the foregoing results, it was confirmed that a certain amount of CoO remains in the sputtering target in Example 1.

### Comparative Example 1

This is a case of not using Co—CoO powder in production of Co—Cr-Cr₂O₃—CoO sputtering target.

A Co powder having an average particle diameter of 3 μm and a Cr powder having an average particle diameter of 5 μm as metal powders, and a CoO powder having an average particle diameter of 1 μm as an oxide powder were prepared. The powders were weighed at the following weight ratio to be 1836.1 g in total.

Weight ratio: 69.32 Co-12.06 Cr-18.62 CoO (wt %)

This weight ratio is represented by the following molecular weight ratio.

Molecular weight ratio: 71 Co-14 Cr-15 CoO (mol %)

Subsequently, the weighed metal powders and oxide powder were placed in a 10-liter ball mill pot together with zirconia balls as a pulverizing medium, and the ball mill pot was sealed and rotated for 2 hours for mixing and pulverization. The powder mixture taken out from the ball mill was filled in a carbon mold and was hot-pressed.

The hot-press conditions were a vacuum atmosphere, a rate of temperature rise of 300° C./hour, a retention temperature of 1050° C., and a retention time of 2 hours, and a pressure of 30 MPa was applied to the mold from the start of the temperature rise till the completion of the retention.

The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 98.1%. A small piece cut from the target was subject to composition analysis with an ICP emission spectrophotometric analyzer. The composition of the sputtering target calculated based on the analytic result was as follows.

90.52 Co-4.05 Cr-5.35 Cr₂O₃-0.08 CoO (mol %)

The volume fraction of Co oxide calculated from the target composition was 0.1 vol %. A part of the sputtering target was cut out, and the cross section thereof was polished to observe the structure. In the structure, Cr oxide was uniformly dispersed in a Co—Cr alloy base, but the presence of CoO was not clearly confirmed.

From the foregoing results, it was confirmed that CoO is decomposed in the sputtering target, and almost no CoO remains in Comparative Example 1.

### Example 2

This is a case of using Co—CoO powder in production of Co—Cr—SiO₂—Cr₂O₃—CoO sputtering target.

A Co powder having an average particle diameter of 3 μm and a Cr powder having an average particle diameter of 5 μm as metal powders, a SiO₂ powder having an average particle diameter of 1 μm as an oxide powder, and a Co—CoO powder having an average particle diameter of 150 μm prepared by pulverizing a sintered compact containing CoO dispersed in Co (composition: Co-25 mol % CoO) were prepared.

The powders were weighed at the following weight ratio to be 1513.4 g in total.

Weight ratio: 50.87 Co-13.20 Cr-6.10 SiO₂-29.83 (Co—CoO) (wt %)

This weight ratio is represented by the following molecular weight ratio.

Molecular weight ratio: 72 Co-15 Cr-6 SiO₂-7 CoO (mol %)

Subsequently, the weighed metal powders and oxide powder were placed in a 10-liter ball mill pot together with zirconia balls as a pulverizing medium, and the ball mill pot was sealed and rotated for 20 hours for mixing and pulverization. The powder mixture taken out from the ball mill was further mixed with the Co—CoO powder with a planetary screw mixer having a ball capacity of about 7 liters for 10 minutes. The powder mixture taken out from the planetary screw mixer was filled in a carbon mold and was hot-pressed.

The hot-press conditions were a vacuum atmosphere, a rate of temperature rise of 300° C./hour, a retention temperature of 1100° C., and a retention time of 2 hours, and a pressure of 30 MPa was applied to the mold from the start of the temperature rise till the completion of the retention.

The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 96.3%. A small piece cut from the sputtering target was subject to composition analysis with an ICP emission spectrophotometric analyzer. The composition of the sputtering target calculated based on the analytic result was as follows.

76.83 Co-12.1 Cr-5.97 SiO₂-1.12 Cr₂O₃-3.98 CoO (mol %)

The volume fraction of Co oxide calculated from the target composition was 5.5 vol %. A part of the sputtering target was cut out, and the cross section thereof was polished to observe the structure. A region (A) containing CoO dispersed in Co and a region (D) containing Cr oxide being present in the periphery of the region (A) were observed.

From the foregoing results, it was confirmed that a certain amount of CoO remains in the sputtering target in Example 2.

### Comparative Example 2

This is a case of not using Co—CoO powder in production of Co—Cr—SiO₂—Cr₂O₃—CoO sputtering target.

In Comparative Example 2, a Co powder having an average particle diameter of 3 μm and a Cr powder having an average particle diameter of 5 μm as metal powders, and a SiO₂ powder having an average particle diameter of 1 μm and a CoO powder having an average particle diameter of 1 μm as oxide powders were prepared. The powders were weighed at the following weight ratio to be 1513.4 g in total.

Weight ratio: 71.82 Co-13.20 Cr-6.10 SiO₂-8.88 CoO (wt %)

This weight ratio is represented by the following molecular weight ratio.

Molecular weight ratio: 72 Co-15 Cr-6 SiO₂-7 CoO (mol %)

Subsequently, the weighed powders were placed in a 10-liter ball mill pot together with zirconia balls as a pulverizing medium, and the ball mill pot was sealed and rotated for 20 hours for mixing and pulverization. The powder mixture taken out from the ball mill was filled in a carbon mold and was hot-pressed.

The hot-press conditions were a vacuum atmosphere, a rate of temperature rise of 300° C./hour, a retention temperature of 1100° C., and a retention time of 2 hours, and a pressure of 30 MPa was applied to the mold from the start of the temperature rise till the completion of the retention. The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 96.9%. A small piece cut from the sputtering target was subject to composition analysis with an ICP emission spectrophotometric analyzer. The composition of the sputtering target calculated based on the analytic result was as follows.

80.80 Co-10.5 Cr-6.12 SiO₂-2.51 Cr₂O₃-0.07 CoO (mol %)

The volume fraction of Co oxide calculated from the target composition was 0.1 vol %. A part of the sputtering target was cut out, and the cross section thereof was polished to observe the structure. In the structure, SiO₂ and Cr oxide were uniformly dispersed in a Co—Cr alloy base, but the presence of CoO was not clearly confirmed.

From the foregoing results, it was confirmed that almost no CoO remains in the sputtering target in Comparative Example 2.

### Example 3

This is a case of using Co—CoO powder in production of Co—Cr—Pt—SiO₂—Cr₂O₃—CoO sputtering target.

A Co powder having an average particle diameter of 3 μm, a Cr powder having an average particle diameter of 5 μm, and a Pt powder having an average particle diameter of 3 μm as metal powders, a SiO₂ powder having an average particle diameter of 1 gm as an oxide powder, and a Co—CoO powder having an average particle diameter of 150 μm prepared by pulverizing a sintered compact containing CoO dispersed in Co (composition: Co-25 mol % CoO) were prepared.

The powders were weighed at the following weight ratio to be 1864.6 g in total.

Weight ratio: 30.48 Co-10.34 Cr-31.04 Pt-4.78 SiO₂-23.36 (Co—CoO) (wt %)

This weight ratio is represented by the following molecular weight ratio.

Molecular weight ratio: 60 Co-15 Cr-12 Pt-6 SiO₂-7 CoO (mol %)

Subsequently, the weighed metal powders and oxide powder were placed in a 10-liter ball mill pot together with zirconia balls as a pulverizing medium, and the ball mill pot was sealed and rotated for 20 hours for mixing and pulverization. The powder mixture taken out from the ball mill was further mixed with the Co—CoO powder with a planetary screw mixer having a ball capacity of about 7 liters for 10 minutes. The powder mixture taken out from the planetary screw mixer was filled in a carbon mold and was hot-pressed.

The hot-press conditions were a vacuum atmosphere, a rate of temperature rise of 300° C./hour, a retention temperature of 1100° C., and a retention time of 2 hours, and a pressure of 30 MPa was applied to the mold from the start of the temperature rise till the completion of the retention.

The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 95.8%. A small piece cut from the sputtering target was subject to composition analysis with an ICP emission spectrophotometric analyzer. The composition of the sputtering target calculated based on the analytic result was as follows.

63.74 Co-12.92 Cr-12.13 Pt-6.07 SiO₂-1.12 Cr₂O₃-4.02 CoO (mol %)

The volume fraction of Co oxide calculated from the target composition was 5.4 vol %. A part of the sputtering target was cut out, and the cross section thereof was polished to observe the structure. A region (A) containing CoO dispersed in Co and a region (D) containing Cr oxide being present in the periphery of the region (A) were observed.

From the foregoing results, it was confirmed that a certain amount of CoO remains in the sputtering target in Example 3.

### Example 4

This is a case of using Pt—CoO powder in production of Co—Cr—Pt—SiO₂—Cr₂O₃—CoO sputtering target.

A Co powder having an average particle diameter of 3 μm, a Cr powder having an average particle diameter of 5 μm, and a Pt powder having an average particle diameter of 3 μm as metal powders, a SiO₂ powder having an average particle diameter of 1 μm as an oxide powder, and a Pt—CoO powder having an average particle diameter of 150 μm prepared by pulverizing a sintered compact containing CoO dispersed in Pt (composition: Pt-40 mol % CoO) were prepared.

The powders were weighed at the following weight ratio to be 1864.6 g in total.

Weight ratio: 46.89 Co-10.34 Cr-3.88 Pt-4.78 SiO₂-34.11 (Pt—CoO) (wt %)

This weight ratio is represented by the following molecular weight ratio.

Molecular weight ratio: 60 Co-15 Cr-12 Pt-6 SiO₂-7 CoO (mol %)

Subsequently, the weighed metal powders and oxide powder were placed in a 10-liter ball mill pot together with zirconia balls as a pulverizing medium, and the ball mill pot was sealed and rotated for 20 hours for mixing and pulverization. The powder mixture taken out from the ball mill was further mixed with the Pt—CoO powder with a planetary screw mixer having a ball capacity of about 7 liters for 10 minutes. The powder mixture taken out from the planetary screw mixer was filled in a carbon mold and was hot-pressed.

The hot-press conditions were a vacuum atmosphere, a rate of temperature rise of 300° C./hour, a retention temperature of 1100° C., and a retention time of 2 hours, and a pressure of 30 MPa was applied to the mold from the start of the temperature rise till the completion of the retention.

The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 96.1%. A small piece cut from the sputtering target was subject to composition analysis with an ICP emission spectrophotometric analyzer. The composition of the sputtering target calculated based on the analytic result was as follows.

63.29 Co-12.99 Cr-12.13 Pt-6.00 SiO₂-1.02 Cr₂O₃-4.57 CoO (mol %)

The volume fraction of Co oxide calculated from the target composition was 6.1 vol %. A part of the sputtering target was cut out, and the cross section thereof was polished to observe the structure. A region (B) containing CoO dispersed in Pt and a region (D) containing Cr oxide being present in the periphery of the region (B) were observed.

From the foregoing results, it was confirmed that a certain amount of CoO remains in the sputtering target in Example 4.

### Example 5

This is a case of using Co—Pt—CoO powder in production of Co—Cr—Pt—SiO₂—Cr₂O₃—CoO sputtering target.

A Co powder having an average particle diameter of 3 μm, a Cr powder having an average particle diameter of 5 μm, and a Pt powder having an average particle diameter of 3 μm as metal powders, a SiO₂ powder having an average particle diameter of 1 μm as an oxide powder, and a Co—Pt—CoO powder having an average particle diameter of 150 μm prepared by pulverizing a sintered compact containing CoO dispersed in a Co—Pt alloy (composition: 37.5 Co-37.5 Pt-25 CoO (mol %)) were prepared.

The powders were weighed at the following weight ratio to be 1864.6 g in total.

Weight ratio: 38.68 Co-10.34 Cr-3.88 Pt-4.78 SiO₂-42.32 (Co—Pt—CoO) (wt %)

This weight ratio is represented by the following molecular weight ratio.

Molecular weight ratio: 60 Co-15 Cr-12 Pt-6 SiO₂-7 CoO (mol %)

Subsequently, the weighed metal powders and oxide powder were placed in a 10-liter ball mill pot together with zirconia balls as a pulverizing medium, and the ball mill pot was sealed and rotated for 20 hours for mixing and pulverization. The powder mixture taken out from the ball mill was further mixed with the Co—Pt—CoO powder with a planetary screw mixer having a ball capacity of about 7 liters for 10 minutes. The powder mixture taken out from the planetary screw mixer was filled in a carbon mold and was hot-pressed.

The hot-press conditions were a vacuum atmosphere, a rate of temperature rise of 300° C./hour, a retention temperature of 1100° C., and a retention time of 2 hours, and a pressure of 30 MPa was applied to the mold from the start of the temperature rise till the completion of the retention.

The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 96.1%. A small piece cut from the target was subject to composition analysis with an ICP emission spectrophotometric analyzer. The composition of the sputtering target calculated based on the analytic result was as follows.

63.83 Co-12.67 Cr-12.08 Pt-6.03 SiO₂-1.18Cr₂O₃-4.21 CoO (mol %)

The volume fraction of Co oxide calculated from the target composition was 5.6 vol %. A part of the sputtering target was cut out, and the cross section thereof was polished to observe the structure. A region (C) containing CoO dispersed in Co—Pt and a region (D) containing Cr oxide being present in the periphery of the region (C) were observed.

From the foregoing results, it was confirmed that a certain amount of CoO remains in the sputtering target in Example 5.

### Comparative Example 3

This is a case of not using Co—CoO powder, Pt—CoO powder, and Co—Pt—CoO powder in production of Co—Cr—Pt—SiO₂—Cr₂O₃—CoO sputtering target.

In Comparative Example 3, a Co powder having an average particle diameter of 3 μm, a Cr powder having an average particle diameter of 5 μm, and a Pt powder having an average particle diameter of 3 μm as metal powders, and a SiO₂ powder having an average particle diameter of 1 μm and a CoO powder having an average particle diameter of 1 μm as oxide powders were prepared. The powders were weighed at the following weight ratio to be 1864.6 g in total.

Weight ratio: 46.89 Co-10.34 Cr-31.04 Pt-4.78 SiO₂-6.95 CoO (wt %)

This weight ratio is represented by the following molecular weight ratio.

Molecular weight ratio: 60 Co-15 Cr-12 Pt-6SiO₂-7 CoO (mol %)

Subsequently, the weighed powders were placed in a 10-liter ball mill pot together with zirconia balls as a pulverizing medium, and the ball mill pot was sealed and rotated for 20 hours for mixing and pulverization. The powder mixture taken out from the ball mill was filled in a carbon mold and was hot-pressed.

The hot-press conditions were a vacuum atmosphere, a rate of temperature rise of 300° C./hour, a retention temperature of 1100° C., and a retention time of 2 hours, and a pressure of 30 MPa was applied to the mold from the start of the temperature rise till the completion of the retention. The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 96.5%. A small piece cut from the sputtering target was subject to composition analysis with an ICP emission spectrophotometric analyzer. The composition of the sputtering target calculated based on the analytic result was as follows.

68.63 Co-10.48 Cr-12.30 Pt-6.10 SiO₂-2.46 Cr₂O₃-0.03 CoO (mol %)

The volume fraction of Co oxide calculated from the target composition was 0.04 vol %. A part of the sputtering target was cut out, and the cross section thereof was polished to observe the structure. In the structure, SiO₂ and Cr oxide were uniformly dispersed in a Co—Cr—Pt base, but the presence of CoO was not clearly confirmed.

From the foregoing results, it was confirmed that almost no CoO remains in the sputtering target in Comparative Example 3.

### Example 6

This is a case of using Co—CoO in production of Co—Cr—Pt—W—SiO₂—Cr₂O₃—CoO sputtering target.

A Co powder having an average particle diameter of 3 μm, a Cr powder having an average particle diameter of 5 μm, a Pt powder having an average particle diameter of 3 μm, and a W powder having an average particle diameter of 2 μm as metal powders, a SiO₂ powder having an average particle diameter of 1 μm as an oxide powder, and a Co—CoO powder having an average particle diameter of 150 μm prepared by pulverizing a sintered compact containing CoO dispersed in Co (composition: Co-25 mol % CoO) were prepared.

The powders were weighed at the following weight ratio to be 1940.6 g in total.

Weight ratio: 27.52 Co-9.19 Cr-29.54 Pt-6.96 W-4.55 SiO₂-22.24 (Co—CoO) (wt %)

This weight ratio is represented by the following molecular weight ratio.

Molecular weight ratio: 58 Co-14 Cr-12 Pt-3 W-6SiO₂-7 CoO (mol %)

Subsequently, the weighed metal powders and oxide powder were placed in a 10-liter ball mill pot together with zirconia balls as a pulverizing medium, and the ball mill pot was sealed and rotated for 20 hours for mixing and pulverization. The powder mixture taken out from the ball mill was further mixed with the Co—CoO powder with a planetary screw mixer having a ball capacity of about 7 liters for 10 minutes. The powder mixture taken out from the planetary screw mixer was filled in a carbon mold and was hot-pressed.

The hot-press conditions were a vacuum atmosphere, a rate of temperature rise of 300° C./hour, a retention temperature of 1100° C., and a retention time of 2 hours, and a pressure of 30 MPa was applied to the mold from the start of the temperature rise till the completion of the retention.

The mold was naturally cooled after the completion of the retention. The thus-produced sintered compact was cut with a lathe into a disk-shaped target having a diameter of 180 mm and a thickness of 5 mm.

The sputtering target at this time had a relative density of 97.3%. A small piece cut from the target was subject to composition analysis with an ICP emission spectrophotometric analyzer. The composition of the sputtering target calculated based on the analytic result was as follows.

61.26 Co-12.22 Cr-12.14 Pt-2.98 W-6.03 SiO₂-0.96 Cr₂O₃-4.41 CoO (mol %)

The volume fraction of Co oxide calculated from the target composition was 5.8 vol %. A part of the sputtering target was cut out, and the cross section thereof was polished to observe the structure. A region (A) containing CoO dispersed in Co and a region (D) containing Cr oxide being present in the periphery of the region (A) were observed.

From the foregoing results, it was confirmed that a certain amount of CoO remains in the sputtering target in Example 6.

### Comparative Example 4

This is a case of not using Co—CoO in the production of Co—Cr—Pt—W—SiO₂—Cr₂O₃—CoO sputtering target.

In Comparative Example 4, a Co powder having an average particle diameter of 3 μm, a Cr powder having an average particle diameter of 5 μm, a Pt powder having an average particle diameter of 3 μm, and a W powder having an average particle diameter of 2 μm as metal powders, and a SiO₂ powder having an average particle diameter of 1 μm and a CoO powder having an average particle diameter of 1 μm as oxide powders were prepared. The powders were weighed at the following weight ratio to be 1940.6 g in total.

Weight ratio: 43.14 Co-9.19 Cr-29.54 Pt-6.96 W-4.55 SiO₂-6.62 CoO (wt %)

This weight ratio is represented by the following molecular weight ratio.

Molecular weight ratio: 58 Co-14 Cr-12 Pt-3 W-6 SiO₂-7 CoO (mol %)

Subsequently, the weighed powders were placed in a 10-liter ball mill pot together with zirconia balls as a pulverizing medium, and the ball mill pot was sealed and rotated for 20 hours for mixing and pulverization. The powder mixture taken out from the ball mill was filled in a carbon mold and was hot-pressed.

The hot-press conditions were a vacuum atmosphere, a rate of temperature rise of 300° C./hour, a retention temperature of 1100° C., and a retention time of 2 hours, and a pressure of 30 MPa was applied to the mold from the start of the temperature rise till the completion of the retention. The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 97.8%. A small piece cut from the sputtering target was subject to composition analysis with an ICP emission spectrophotometric analyzer. The composition of the sputtering target calculated based on the analytic result was as follows.

66.59 Co-9.40 Cr-12.25 Pt-3.02 W-6.10 SiO₂-2.55 Cr₂O₃-0.09 CoO (mol %)

The volume fraction of Co oxide calculated from the target composition was 0.1 vol %. A part of the sputtering target was cut out, and the cross section thereof was polished to observe the structure. In the structure, SiO₂ and Cr oxide were uniformly dispersed in a Co—Cr—Pt—W base, but the presence of CoO was not clearly confirmed.

From the foregoing results, it was confirmed that almost no CoO remains in the sputtering target in Comparative Example 4.

### Example 7

This is a case of using Co—CoO in production of Co—Cr—Pt—Ru—TiO₂—SiO₂—Cr₂O₃—CoO sputtering target.

A Co powder having an average particle diameter of 3 μm, a Cr powder having an average particle diameter of 5 μm, a Pt powder having an average particle diameter of 3 μm, and a Ru powder having an average particle diameter of 5 μm as metal powders, and TiO₂ having an average particle size of 1 μm and a SiO₂ having an average particle size of 1 μm as oxide powders, and a Co—CoO powder having an average particle diameter of 150 μm prepared by pulverizing a sintered compact containing CoO dispersed in Co (composition: Co-25 mol % CoO) were prepared.

The powders were weighed at the following weight ratio to be 1935.3 g in total.

Weight ratio: 28.26 Co-9.44 Cr-30.34 Pt-3.93 Ru-2.07 TiO₂-3.12 SiO₂-22.84 (Co—CoO) (wt %)

This weight ratio is represented by the following molecular weight ratio.

Molecular weight ratio: 58 Co-14 Cr-12 Pt-3 Ru-2 TiO₂-4 SiO₂-7 CoO (mol %)

Subsequently, the weighed metal powders and oxide powders were placed in a 10-liter ball mill pot together with zirconia balls as a pulverizing medium, and the ball mill pot was sealed and rotated for 20 hours for mixing and pulverization. The powder mixture taken out from the ball mill was further mixed with the Co—CoO powder with a planetary screw mixer having a ball capacity of about 7 liters for 10 minutes. The powder mixture taken out from the planetary screw mixer was filled in a carbon mold and was hot-pressed.

The hot-press conditions were a vacuum atmosphere, a rate of temperature rise of 300° C./hour, a retention temperature of 1100° C., and a retention time of 2 hours, and a pressure of 30 MPa was applied to the mold from the start of the temperature rise till the completion of the retention.

The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 98.6%. A small piece cut from the sputtering target was subject to composition analysis with an ICP emission spectrophotometric analyzer. The composition of the sputtering target calculated based on the analytic result was as follows.

61.91 Co-12.16 Cr-12.14 Pt-2.98 Ru-1.96 TiO₂-4.03 SiO₂-0.96 Cr₂O₃-3.86 CoO (mol %)

The volume fraction of Co oxide calculated from the target composition was 5.3 vol %. A part of the sputtering target was cut out, and the cross section thereof was polished to observe the structure. A region (A) containing CoO dispersed in Co and a region (D) containing Cr oxide being present in the periphery of the region (A) were observed.

From the foregoing results, it was confirmed that a certain amount of CoO remains in the sputtering target in Example 7.

### Comparative Example 5

This is a case of not using Co—CoO in production of Co—Cr—Pt—Ru—TiO₂-SiO₂—Cr₂O₃—CoO sputtering target.

In Comparative Example 5, a Co powder having an average particle diameter of 3 gm, a Cr powder having an average particle diameter of 5 μm, a Pt powder having an average particle diameter of 3 gm, and a Ru powder having an average particle diameter of 5 gm as metal powders, and a TiO₂ powder having an average particle size of 1 μm, a SiO₂ powder having an average particle diameter of 1 μm, and a CoO powder having an average particle diameter of 1 gm as oxide powders were prepared. The powders were weighed at the following weight ratio to be 1935.3 g in total.

Weight ratio: 44.30 Co-9.44 Cr-30.34 Pt-3.93 Ru-2.07 TiO2-3.12 SiO2-6.80 CoO (wt %)

This weight ratio is represented by the following molecular weight ratio.

Molecular weight ratio: 58 Co-14 Cr-12 Pt-3 Ru-2 TiO₂-4 SiO₂-7 CoO (mol %)

Subsequently, the weighed powders were placed in a 10-liter ball mill pot together with zirconia balls as a pulverizing medium, and the ball mill pot was sealed and rotated for 20 hours for mixing and pulverization. The powder mixture taken out from the ball mill was filled in a carbon mold and was hot-pressed.

The hot-press conditions were a vacuum atmosphere, a rate of temperature rise of 300° C./hour, a retention temperature of 1100° C., and a retention time of 2 hours, and a pressure of 30 MPa was applied to the mold from the start of the temperature rise till the completion of the retention. The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 98.3%. A small piece cut from the sputtering target was subject to composition analysis with an ICP emission spectrophotometric analyzer. The composition of the sputtering target calculated based on the analytic result was as follows.

66.66 Co-8.99 Cr-12.28 Pt-3.02 Ru-2.00 TiO₂-4.07 SiO₂-2.96 Cr₂O₃-0.02 CoO (mol %)

The volume fraction of Co oxide calculated from the target composition was 0.03 vol %. A part of the sputtering target was cut out, and the cross section thereof was polished to observe the structure. In the structure, TiO₂, SiO₂, and Cr oxide were uniformly dispersed in a Co—Cr—Pt—Ru base, but the presence of CoO was not clearly confirmed.

From the foregoing results, it was confirmed that almost no CoO remains in the sputtering target in Comparative Example 5.

### Example 8

This is a case of using Co—CoO in production of Co—Cr—Pt—B₂O₃—SiO₂—Cr₂O₃—CoO sputtering target.

A Co powder having an average particle diameter of 3 gm, a Cr powder having an average particle diameter of 5 μm, and a Pt powder having an average particle diameter of 3 μm as metal powders, and a B₂O₃ powder having an average particle diameter of 20 gm and SiO₂ having an average particle size of 1 μm as oxide powders, and a Co—CoO powder having an average particle diameter of 150 μm prepared by pulverizing a sintered compact containing CoO dispersed in Co (composition: Co-25 mol % CoO) were prepared.

The powders were weighed at the following weight ratio to be 1900.0 g in total.

Weight ratio: 30.36 Co-9.62 Cr-30.93 Pt-1.84 B₂O₃-3.97 SiO₂-23.28 (Co—CoO) (wt %)

This weight ratio is represented by the following molecular weight ratio.

Molecular weight ratio: 60 Co-14 Cr-12 Pt-2 B₂O₃-5 SiO₂-7 CoO (mol %)

Subsequently, the weighed metal powders and the oxide powders were placed in a 10-liter ball mill pot together with zirconia balls as a pulverizing medium, and the ball mill pot was sealed and rotated for 20 hours for mixing and pulverization. The powder mixture taken out from the ball mill was further mixed with the Co—CoO powder with a planetary screw mixer having a ball capacity of about 7 liters for 10 minutes. The powder mixture taken out from the planetary screw mixer was filled in a carbon mold and was hot-pressed.

The hot-press conditions were a vacuum atmosphere, a rate of temperature rise of 300° C./hour, a retention temperature of 1000° C., and a retention time of 2 hours, and a pressure of 30 MPa was applied to the mold from the start of the temperature rise till the completion of the retention.

The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 98.2%. A small piece cut from the sputtering target was subject to composition analysis with an ICP emission spectrophotometric analyzer. The composition of the sputtering target calculated based on the analytic result was as follows.

65.32 Co-11.29 Cr-12.20Pt-1.93 B₂O₃-5.10 SiO₂-1.32 Cr₂O₃-2.84 CoO (mol %)

The volume fraction of Co oxide calculated from the target composition was 3.6 vol %. A part of the sputtering target was cut out, and the cross section thereof was polished to observe the structure. A region (A) containing CoO dispersed in Co and a region (D) containing Cr oxide being present in the periphery of the region (A) were observed.

From the foregoing results, it was confirmed that a certain amount of CoO remains in the sputtering target in Example 8.

### Comparative Example 6

This is a case of not using Co—CoO in production of Co—Cr—Pt—B₂O₃—SiO₂—Cr₂O₃—CoO sputtering target.

In Comparative Example 6, a Co powder having an average particle diameter of 3 μm, a Cr powder having an average particle diameter of 5 μm, and a Pt powder having an average particle diameter of 3 μm as metal powders, and a B₂O₃ powder having an average particle diameter of 20 μm, a SiO₂ powder having an average particle diameter of 1 μm, and a CoO powder having an average particle diameter of 1 μm as oxide powders were prepared. The powders were weighed at the following weight ratio to be 1900.0 g in total.

Weight ratio: 46.71 Co-9.62 Cr-30.93 Pt-1.84 B₂O₃-3.97 SiO₂-6.93 CoO (wt %)

This weight ratio is represented by the following molecular weight ratio.

Molecular weight ratio: 60 Co-14 Cr-12 Pt-2 B₂O₃-5 SiO₂-7 CoO (mol %)

Subsequently, the weighed powders were placed in a 10-liter ball mill pot together with zirconia balls as a pulverizing medium, and the ball mill pot was sealed and rotated for 20 hours for mixing and pulverization. The powder mixture taken out from the ball mill was filled in a carbon mold and was hot-pressed.

The hot-press conditions were a vacuum atmosphere, a rate of temperature rise of 300° C./hour, a retention temperature of 1000° C., and a retention time of 2 hours, and a pressure of 30 MPa was applied to the mold from the start of the temperature rise till the completion of the retention. The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 98.4%. A small piece cut from the sputtering target was subject to composition analysis with an ICP emission spectrophotometric analyzer. The composition of the sputtering target calculated based on the analytic result was as follows.

Molecular weight ratio: 68.58 Co-9.48 Cr-12.32 Pt-1.95 B₂O₃-5.21 SiO₂-2.36 Cr₂O₃-0.10 CoO (mol %)

The volume fraction of Co oxide calculated from the target composition was 0.1 vol %. A part of the sputtering target was cut out, and the cross section thereof was polished to observe the structure. In the structure, B₂O₃, SiO₂, and Cr oxide were uniformly dispersed in a Co—Cr—Pt base, but the presence of CoO was not clearly confirmed.

From the foregoing results, it was confirmed that almost no CoO remains in the sputtering target in Comparative Example 6.

### Example 9

This is a case of using Co—CoO in production of Co—Cr—Pt—Ta₂O₅—Cr₂O₃—CoO sputtering target.

A Co powder having an average particle diameter of 3 gm, a Cr powder having an average particle diameter of 5 μm, and a Pt powder having an average particle diameter of 3 μm as metal powders, and Ta₂O₅ having an average particle diameter of 2 gm as an oxide powder, and a Co—CoO powder having an average particle diameter of 150 μm prepared by pulverizing a sintered compact containing CoO dispersed in Co (composition: Co-25 mol % CoO) were prepared.

The powders were weighed at the following weight ratio to be 2290.0 g in total.

Weight ratio: 34.51 Co-9.84 Cr-27.69 Pt-13.07 Ta₂O₅-14.89 (Co—CoO) (wt %)

This weight ratio is represented by the following molecular weight ratio.

Molecular weight ratio: 64.5 Co-16 Cr-12 Pt-2.5 Ta₂O₅-5 CoO (mol %)

Subsequently, the weighed metal powders and oxide powder were placed in a 10-liter ball mill pot together with zirconia balls as a pulverizing medium, and the ball mill pot was sealed and rotated for 20 hours for mixing and pulverization. The powder mixture taken out from the ball mill was further mixed with the Co—CoO powder with a planetary screw mixer having a ball capacity of about 7 liters for 10 minutes. The powder mixture taken out from the planetary screw mixer was filled in a carbon mold and was hot-pressed.

The hot-press conditions were a vacuum atmosphere, a rate of temperature rise of 300° C./hour, a retention temperature of 1100° C., and a retention time of 2 hours, and a pressure of 30 MPa was applied to the mold from the start of the temperature rise till the completion of the retention.

The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 99.3%. A small piece cut from the sputtering target was subject to composition analysis with an ICP emission spectrophotometric analyzer. The composition of the sputtering target calculated based on the analytic result was as follows.

68.50 Co-13.98 Cr-12.10 Pt-2.57 Ta₂O₅-1.02 Cr₂O₃-1.83 CoO (mol %)

The volume fraction of Co oxide calculated from the target composition was 2.5 vol %. A part of the sputtering target was cut out, and the cross section thereof was polished to observe the structure. A region (A) containing CoO dispersed in Co and a region (D) containing Cr oxide being present in the periphery of the region (A) were observed.

From the foregoing results, it was confirmed that a certain amount of CoO remains in the sputtering target in Example 9.

### Comparative Example 7

This is a case of not using Co—CoO in production of Co—Cr—Pt—Ta₂O₅—Cr₂O₃—CoO sputtering target.

In Comparative Example 7, a Co powder having an average particle diameter of 3 μm, a Cr powder having an average particle diameter of 5 μm, and a Pt powder having an average particle diameter of 3 μm as metal powders, and a Ta₂O₅ powder having an average particle diameter of 2 μm and a CoO powder having an average particle diameter of 1 μm as oxide powders were prepared. The powders were weighed at the following weight ratio to be 2290.0 g in total.

Weight ratio: 44.97 Co-9.84 Cr-27.69 Pt-13.07 Ta₂O₅-4.43 CoO (wt %)

This weight ratio is represented by the following molecular weight ratio.

Molecular weight ratio: 64.5 Co-16 Cr-12 Pt-2.5 Ta₂O₅-5 CoO (mol %)

Subsequently, the weighed powders were placed in a 10-liter ball mill pot together with zirconia balls as a pulverizing medium, and the ball mill pot was sealed and rotated for 20 hours for mixing and pulverization. The powder mixture taken out from the ball mill was filled in a carbon mold and was hot-pressed.

The hot-press conditions were a vacuum atmosphere, a rate of temperature rise of 300° C./hour, a retention temperature of 1100° C., and a retention time of 2 hours, and a pressure of 30 MPa was applied to the mold from the start of the temperature rise till the completion of the retention. The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 99.6%. A small piece cut from the sputtering target was subject to composition analysis with an ICP emission spectrophotometric analyzer. The composition of the sputtering target calculated based on the analytic result was as follows.

70.82 Co-12.75 Cr-12.25 Pt-2.55 Ta₂O₅-1.60 Cr₂O₃-0.03 CoO (mol %)

The volume fraction of Co oxide calculated from the target composition was 0.04 vol %. A part of the sputtering target was cut out, and the cross section thereof was polished to observe the structure. In the structure, Ta₂O₅ and Cr oxide were uniformly dispersed in a Co—Cr—Pt base, but the presence of CoO was not clearly confirmed.

From the foregoing results, it was confirmed that almost no CoO remains in the sputtering target in Comparative Example 7.

### Example 10

This is a case of using Pt—Co₃O₄ in production of Co—Cr—Pt—SiO₂—Cr₂O₃—Co₃O₄ sputtering target.

A Co powder having an average particle diameter of 3 μm, a Cr powder having an average particle diameter of 5 μm, and a Pt powder having an average particle diameter of 3 μm as metal powders, and a SiO₂ powder having an average particle diameter of 2 μm as an oxide powder, and a Pt-Co₃O₄ powder having an average particle diameter of 150 μm prepared by pulverizing a sintered compact containing Co₃O₄ dispersed in Pt (composition: Pt-10 mol %Co₃O₄) were prepared.

The powders were weighed at the following weight ratio to be 2090.0 g in total.

Weight ratio: 46.12 Co-7.63 Cr-16.70 Pt-5.14 SiO₂-24.41 (Pt—Co₃O₄) (wt %)

This weight ratio is represented by the following molecular weight ratio.

Molecular weight ratio: 64 Co-12 Cr-16 Pt-7 SiO₂-1 Co₃O₄ (mol %)

Subsequently, the weighed metal powders and oxide powder were placed in a 10-liter ball mill pot together with zirconia balls as a pulverizing medium, and the ball mill pot was sealed and rotated for 20 hours for mixing and pulverization. The powder mixture taken out from the ball mill was further mixed with the Pt—Co₃O₄ powder with a planetary screw mixer having a ball capacity of about 7 liters for 10 minutes. The powder mixture taken out from the planetary screw mixer was filled in a carbon mold and was hot-pressed.

The hot-press conditions were a vacuum atmosphere, a rate of temperature rise of 300° C./hour, a retention temperature of 1100° C., and a retention time of 2 hours, and a pressure of 30 MPa was applied to the mold from the start of the temperature rise till the completion of the retention.

The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 96.8%. A small piece cut from the sputtering target was subject to composition analysis with an ICP emission spectrophotometric analyzer. The composition of the sputtering target calculated based on the analytic result was as follows.

65.69 Co-10.17 Cr-15.95 Pt-7.02 SiO₂-0.80 Cr₂O₃-0.37 Co₃O₄ (mol %)

The volume fraction of Co oxide calculated from the target composition was 1.7 vol %. A part of the sputtering target was cut out, and the cross section thereof was polished to observe the structure. A region (B) containing Co₃O₄ dispersed in Pt and a region (D) containing Cr oxide being present in the periphery of the region (B) were observed.

From the foregoing results, it was confirmed that a certain amount of Co₃O₄ remains in the sputtering target in Example 10.

### Comparative Example 8

This is a case of not using Pt—Co₃O₄ in production of Co—Cr—Pt—SiO₂—Cr₂O₃—Co₃O₄ sputtering target.

In Comparative Example 8, a Co powder having an average particle diameter of 3 μm, a Cr powder having an average particle diameter of 5 μm, and a Pt powder having an average particle diameter of 3 μm as metal powders, and a SiO₂ powder having an average particle diameter of 1 μm and a Co₃O₄ powder having an average particle size of 1 μm as oxide powders were prepared. The powders were weighed at the following weight ratio to be 2090.0 g in total.

Weight ratio: 46.12 Co-7.63 Cr-38.17 Pt-5.14 SiO₂-2.94 Co₃O₄ (wt %)

This weight ratio is represented by the following molecular weight ratio.

Molecular weight ratio: 64 Co-12 Cr-16 Pt-7 SiO₂-1 Co₃O₄ (mol %)

Subsequently, the weighed powders were placed in a 10-liter ball mill pot together with zirconia balls as a pulverizing medium, and the ball mill pot was sealed and rotated for 20 hours for mixing and pulverization. The powder mixture taken out from the ball mill was filled in a carbon mold and was hot-pressed.

The hot-press conditions were a vacuum atmosphere, a rate of temperature rise of 300° C./hour, a retention temperature of 1100° C., and a retention time of 2 hours, and a pressure of 30 MPa was applied to the mold from the start of the temperature rise till the completion of the retention. The mold was naturally cooled after the completion of the retention. The thus-produced sintered compact was cut with a lathe into a disk-shaped sputtering target having a diameter of 180 mm and a thickness of 5 mm.

The sputtering target at this time had a relative density of 97.3%. A small piece cut from the sputtering target was subject to composition analysis with an ICP emission spectrophotometric analyzer. The composition of the sputtering target calculated based on the analytic result was as follows.

66.72 Co-9.20 Cr-15.87 Pt-6.98 SiO₂-1.23 Cr₂O₃-0.00 Co₃O₄ (mol %)

Since Co₃O₄ was not contained, its composition was represented as 0.00. A part of the sputtering target was cut out, and the cross section thereof was polished to observe the structure. In the structure, SiO₂ and Cr oxide were uniformly dispersed in a Co—Cr—Pt base, but the presence of Co₃O₄ was not clearly confirmed.

From the foregoing results, it was confirmed that almost no Co₃O₄ remains in the sputtering target in Comparative Example 8.

The above-described examples show typical examples. In addition, though the amount of Co oxide described in the appended claims does not cover the entire possible range, effects to those of the above-described examples were confirmed in the volume fraction of Co oxide of 1 vol % or more and 20 vol % or less with respect to the sputtering target.

The present invention can provide Co—Cr-oxide system and Co—Cr—Pt-oxide system sintered compact sputtering targets having regions (A) containing Co oxide dispersed in Co. In the periphery of the region (A) containing dispersed Co oxide, a region (D) containing Cr oxide is formed by a reaction of Co oxide with Cr diffused during the sintering. The use of a powder prepared by pulverizing a sintered compact containing Co oxide dispersed in Co as a sintering raw material prevents Co oxide from coming into direct and full-scale contact with Cr even in a temperature range in which the sintering reaction sufficiently proceeds. That is, Co functions as a buffer to prevent the contact, and thereby the region where effective Co oxide is dispersed can be maintained in the sintered compact sputtering target.

Thus, the present invention can provide Co—Cr-oxide system and Co—Cr—Pt-oxide system magnetic material targets that have Co oxide dispersed in Co remaining and have a sufficient sintering density to decrease the occurrence of particles during sputtering. It is therefore possible to form a granular magnetic film having satisfactory magnetic characteristics without causing a reduction in yield due to occurrence of particles. In particular, the present invention contributes to an increase in recording density and a reduction in noise in a hard disk medium employing a perpendicular magnetic recording system.

1. A sintered compact sputtering target comprising:
a metal base containing Co and Cr as the metal components; and
an oxide dispersed in the metal base,
wherein the sputtering target has a structure in which a region (A) containing Co oxide dispersed in Co and a region (D) containing Cr oxide and being present in a periphery of the region (A) are included in the metal base, and
wherein the region (A) does not contain Cr oxide, and the region (D) does not contain Co oxide.

2. The sintered compact sputtering target according to claim 1, wherein the target comprises Cr in an amount of 0.5 mol % or more and 45 mol % or less.

3. A sintered compact sputtering target comprising:
a metal base containing Co, Cr, and Pt as metal components; and
an oxide dispersed in the metal base,
wherein the sputtering target has a structure in which a region (A) containing Co oxide dispersed in Co or a region (B) containing Co oxide dispersed in Pt or a region (C) containing Co oxide dispersed in Co—Pt and a region (D) containing Cr oxide and being present in a periphery of the region (A), (B), or (C) are included in the metal base, and
wherein the region (A), (B), and (C) do not contain Cr oxide, and the region (D) does not contain Co oxide.

4. The sintered compact sputtering target according to claim 3, wherein the target comprises Cr in an amount of 0.5 mol % or more and 30 mol % or less and Pt in an amount of 0.5 mol % or more and 30 mol % or less.

5. The sintered compact sputtering target according to claim 4, wherein the Co oxide is at least one selected from CoO, Co₂O₃, and Co₃O₄.

6. The sintered compact sputtering target according to claim 5, wherein the Co oxide has a volume fraction of 1 vol % or more and 20 vol % or less with respect to a total volume of the sputtering target.

7. The sintered compact sputtering target according to claim 6, further comprising at least one oxide of an element selected from the group consisting of Co, Cr, Mg, B, Al, Si, Ti, V, Mn, Y, Zr, Nb, Ta, and Ce as an oxide dispersed in the metal base in a region other than the region (A), (B), or (C) and the region (D).

8. The sintered compact sputtering target according to claim 7, further comprising at least one element selected from the group consisting of B, Ti, V, Nb, Mo, Ru, Ta, W, Ir, and Au in an amount of 15 mol % or less as a one of the metal components of the metal base.

9. The sintered compact sputtering target according to claim 8, wherein the sputtering target has a relative density of 90% or more.

10. A method of producing a sintered compact sputtering target comprising a metal base containing Co and Cr as metal components and an oxide dispersed in the base, the method comprising the steps of:
mixing a powder prepared by pulverizing a sintered compact containing Co oxide dispersed in Co, a Co powder, and a Cr power; and
pressure-sintering the resulting powder mixture to provide a sputtering target having a structure in which a region (A) containing Co oxide dispersed in Co and a region (D) containing Cr oxide and being present in a periphery of the region (A) are included in the metal base, wherein the region (A) does not contain Cr oxide, and the region (D) does not contain Co oxide.

11. The method of producing a sintered compact sputtering target according to claim 10, wherein the target comprises Cr in an amount of 0.5 mol % or more and 45 mol % or less.

12. A method of producing a sintered compact sputtering target comprising a metal base containing Co, Cr, and Pt as the metal components and an oxide dispersed in the base, the method comprising the steps of:
mixing a powder prepared by pulverizing a sintered compact containing Co oxide dispersed in Co, Pt, or Co—Pt, a Co powder, a Pt powder, and a Cr power; and
pressure-sintering the resulting powder mixture to provide a sputtering target having a structure in which a region (A) containing Co oxide dispersed in Co or a region (B) containing Co oxide dispersed in Pt or a region (C) containing Co oxide dispersed in Co—Pt and a region (D) containing Cr oxide and being present in a periphery of the region (A), (B), or (C) are included in the metal base, wherein the region (A), (B), and (C) do not contain Cr oxide, and the region (D) does not contain Co oxide.

13. The method of producing a sintered compact sputtering target according to claim 12, wherein the target comprises Cr in an amount of 0.5 mol % or more and 30 mol % or less and Pt in an amount of 0.5 mol % or more and 30 mol % or less.

14. The method of producing a sintered compact sputtering target according to claim 13, wherein the Co oxide is at least one selected from the group consisting of CoO, Co₂O₃, and CO₃O₄.

15. The method of producing a sintered compact sputtering target according to claim 14, wherein the Co oxide has a volume fraction of 1 vol % or more and 20 vol % or less with respect to a total volume of the sputtering target.

16. The method of producing a sintered compact sputtering target according to claim 15, wherein the powder mixture for sintering further comprises at least one oxide of an element selected from the group consisting of Co, Cr, B, Mg, Al, Si, Ti, V, Mn, Y, Zr, Nb, Ta, and Ce as an oxide to be dispersed in the metal base in a region other than the region (A), (B), or (C) and the region (D).

17. The method of producing a sintered compact sputtering target according to claim 16, wherein the metal powder for sintering further comprises at least one element selected from the group consisting of B, Ti, V, Nb, Mo, Ru, Ta, W, Ir, and Au in an amount of 15 mol % or less as a one of the metal components of the base metal.

18. The method of producing a sintered compact sputtering target according to claim 17, wherein the sintered compact target has a relative density of 90% or more.

19. The sintered compact sputtering target according to claim 2, wherein the Co oxide is at least one selected from the group consisting of CoO, CO₂O₃, and Co₃O₄.

20. The sintered compact sputtering target according to claim 19, wherein the Co oxide has a volume fraction of 1 vol % or more and 20 vol % or less with respect to a total volume of the sputtering target.
